(19) United States
(12) Patent Application Publication
(10) Pub. No.: US 2025/0379134 A1
(43) Pub. Date: Dec. 11, 2025

(54) INTEGRATED CIRCUIT PACKAGE COMPRISING A SUBSTRATE AND A SOLDER JOINT COUPLED TO A CORNER INTERCONNECT STRUCTURE OF THE SUBSTRATE TO IMPROVE THE RELIABILITY OF THE PACKAGE

(71) Applicant: QUALCOMM Incorporated, San Diego, CA (US)

(72) Inventors: Aniket Patil, San Diego, CA (US); Brian Roggeman, Poway, CA (US); Manuel Aldrete, Encinitas, CA (US); Changho Kim, San Marcos, CA (US)

(21) Appl. No.: 18/734,024

(22) Filed: Jun. 5, 2024

(51) Int. Cl. H01L 23/498

(52) U.S. Cl. CPC H01L 23/49838; H01L 23/49816

(57) ABSTRACT

Aspects disclosed include an integrated circuit (IC) package comprising a substrate and a solder joint coupled to a corner interconnect structure of the substrate to improve the reliability of the package. Related apparatus and methods are also disclosed. The substrate includes the corner interconnect structure in a corner of the substrate. The corner interconnect structure includes a first metal interconnect adjacent to the corner of the substrate and a plurality of second metal interconnects adjacent to the first metal interconnect. The IC package includes a solder joint coupled to at least two of the metal interconnects in the corner interconnect structure improving the mechanical reliability of the IC package. In so doing, a plurality of third metal interconnects adjacent to the corner interconnect structure may be utilized for input/output (I/O) communication paths increasing the input/output of the IC package without growing the size of the package.

### TECHNICAL FIELD

The technology of the disclosure relates to integrated circuit (IC) packaging.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The package substrate includes one or more metallization layers that include metal interconnects (e.g., metal traces, metal lines) with vertical interconnect accesses (vias) coupling the metal interconnects together between adjacent metallization layers to provide electrical interfaces between the die(s). The die(s) is electrically interfaced to metal interconnects exposed in a top or outer layer of the package substrate to electrically couple the die(s) to the metal interconnects of the package substrate. The package substrate includes an outer metallization layer that includes metal interconnects (e.g., metal pads) coupled to external metal interconnects (e.g., solder bumps) to provide an external interface between the die(s) in the IC package for mounting the IC package on a circuit board to interface the die(s) with other circuitry. The package substrate may include an embedded trace substrate (ETS) (or include a thin ETS metallization layer) adjacent to the die to facilitate higher density bumps/solder joints for coupling the die(s) to the package substrate.

Some IC packages are known as “hybrid” IC packages. Hybrid IC packages include multiple dies for different purposes or applications. For example, a hybrid IC package may include an application die, such as a communications modem or processor (including a system). The hybrid IC package could also include one or more memory dies to provide memory to support data storage and access by the application die. The multiple dies can be provided in their own respective die packages that are stacked on top of each other within an overall IC package to reduce the cross-sectional area of the package, known as a stacked-die IC package. In a stacked-die IC package, a first die package is provided that includes a first, bottom die supported by a first, bottom substrate. First die interconnects of the first die are coupled to metal interconnects in the first substrate that are connected to external interconnects (e.g., solder bumps) and other interface interconnects to provide an electrical signal interface to the first die. A second die package that includes a second die is stacked above the first die package in the stacked-die IC package. The second die is electrically coupled through second die interconnects to metal interconnects in a second substrate of the second die package. To provide support and interconnectivity between the second die package and the first die package for die-to-die (D2D) connections as well as between the second die and the external interconnects, the first die package can include an interposer substrate that is disposed adjacent to the first die between the first die package and the second die package. The second die package is coupled to the interposer substrate to provide a connection interface between the first die package and the second die package for D2D and external connections.

### SUMMARY OF THE DISCLOSURE

Aspects disclosed in the detailed description include an integrated circuit (IC) package comprising a substrate and a solder joint coupled to a corner interconnect structure of the substrate to improve the reliability of the package. Related apparatus and methods are also disclosed. The substrate includes the corner interconnect structure in a corner of the substrate. The corner interconnect structure includes a first metal interconnect adjacent to the corner of the substrate and a plurality of second metal interconnects adjacent to the first metal interconnect. The IC package includes a solder joint coupled to at least two of the metal interconnects in the corner interconnect structure improving the mechanical reliability of the IC package. In so doing, a plurality of third metal interconnects adjacent to the corner interconnect structure may be utilized for input/output (I/O) communication paths advantageously increasing the I/O of the IC package without growing the size of the package.

In one aspect, an integrated circuit (IC) package is disclosed. The IC package comprises a substrate. The substrate comprises a plurality of corners and a corner interconnect structure. The corner interconnect structure comprises a first metal interconnect adjacent to a first corner of the plurality of corners and a plurality of second metal interconnects adjacent to the first metal interconnect. The substrate also comprises a plurality of third metal interconnects adjacent to the corner interconnect structure. The IC package also comprises a first solder joint coupled to at least two metal interconnects selected from a group consisting of the plurality of second metal interconnects and the first metal interconnect of the corner interconnect structure.

In another aspect, a method of fabricating an integrated circuit (IC) package is disclosed. The method comprises fabricating a substrate having a plurality of corners. Fabricating the substrate comprises fabricating a corner interconnect structure. Fabricating the corner interconnect structure comprises fabricating a first metal interconnect adjacent to a first corner of the plurality of corners and fabricating a plurality of second metal interconnects adjacent to the first metal interconnect. Fabricating the substrate further comprises fabricating a plurality of third metal interconnects adjacent to the corner interconnect structure. The method further comprises coupling a first solder joint to at least two metal interconnects selected from a group consisting of the plurality of second metal interconnects and the first metal interconnect of the corner interconnect structure.

### BRIEF DESCRIPTION OF THE FIGURES

FIG. 1A is a bottom view of an IC package utilizing a set of dummy solder balls in a corner of an integrated circuit (IC) package;

FIG. 1B is close-up view of FIG. 1A at cut line A1;

FIG. 2 is a bottom view of an IC package comprising a substrate and a solder joint coupled to a corner interconnect structure of the substrate to improve the reliability of the package;

FIG. 3A is a close-up view of FIG. 2 at cut line B1 including an exemplary embodiment of a solder joint coupled to the corner interconnect structure deployed at one or more corner areas of the substrate of FIG. 2;

FIG. 3B is horizontal view of the exemplary embodiment of FIG. 3A;

FIG. 3C is horizontal view of the exemplary embodiment of FIG. 3B wherein the corner interconnect structure is connected to a ground plane;

FIG. 4 is a close-up view of FIG. 2 at cut line B1 including another exemplary embodiment of a solder joint coupled to the corner interconnect structure deployed at one or more corner areas of the substrate of FIG. 2;

FIG. 5 is a close-up view of FIG. 2 at cut line B1 including another exemplary embodiment of a solder joint coupled to the corner interconnect structure deployed at one or more corner areas of the substrate of FIG. 2;

FIG. 6 is a close-up view of FIG. 2 at cut line B1 including another exemplary embodiment of a solder joint coupled to the corner interconnect structure deployed at one or more corner areas of the substrate of FIG. 2;

FIG. 7 is a flowchart illustrating exemplary fabrication process of fabricating an IC package comprising a solder joint coupled to a corner interconnect structure including, but not limited to, the solder joints in FIGS. 3A-3C and 4-6;

FIGS. 8A-8C is a flowchart illustrating another exemplary fabrication process of fabricating a solder joint coupled to a corner interconnect structure including, but not limited to, the solder joints in FIGS. 3A-3C and 4-6;

FIGS. 9A-9F are exemplary fabrication stages during fabrication of the solder joint and corner interconnect structure according to the fabrication process in FIGS. 8A-8C;

FIG. 10 is a block diagram of an exemplary wireless communications device that includes radio-frequency (RF) components deployed in an IC package, wherein the IC package includes a substrate and a solder joint coupled to a corner interconnect structure of the substrate to improve the reliability of the package, including, but not limited to, the IC package in FIG. 2 and the exemplary embodiments of a solder joint coupled to the corner interconnect structure in FIGS. 3A-3C, and 4-6 according to the exemplary fabrication processes in FIGS. 8 and 8A-8C; and

FIG. 11 is a block diagram of an exemplary processor-based system that can include components deployed in an IC package, wherein the IC package includes a substrate and a solder joint coupled to a corner interconnect structure of the substrate to improve the reliability of the package, including, but not limited to, the IC package in FIG. 2 and the exemplary embodiments of a solder joint coupled to the corner interconnect structure in FIGS. 3A-3C, and 4-6 according to the exemplary fabrication processes in FIGS. 8 and 8A-8C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein means spatially next to but not necessarily adjoining something as shown in the Figures unless specifically stated otherwise.

Aspects disclosed in the detailed description include an integrated circuit (IC) package comprising a substrate and a solder joint coupled to a corner interconnect structure of the substrate to improve the reliability of the package. Related apparatus and methods are also disclosed. The substrate includes the corner interconnect structure in a corner of the substrate. The corner interconnect structure includes a first metal interconnect adjacent to the corner of the substrate and a plurality of second metal interconnects adjacent to the first metal interconnect. The IC package includes a solder joint coupled to at least two of the metal interconnects in the corner interconnect structure improving the mechanical reliability of the IC package. In so doing, a plurality of third metal interconnects adjacent to the corner interconnect structure may be utilized for input/output (I/O) communication paths increasing the input/output of the IC package without growing the size of the package.

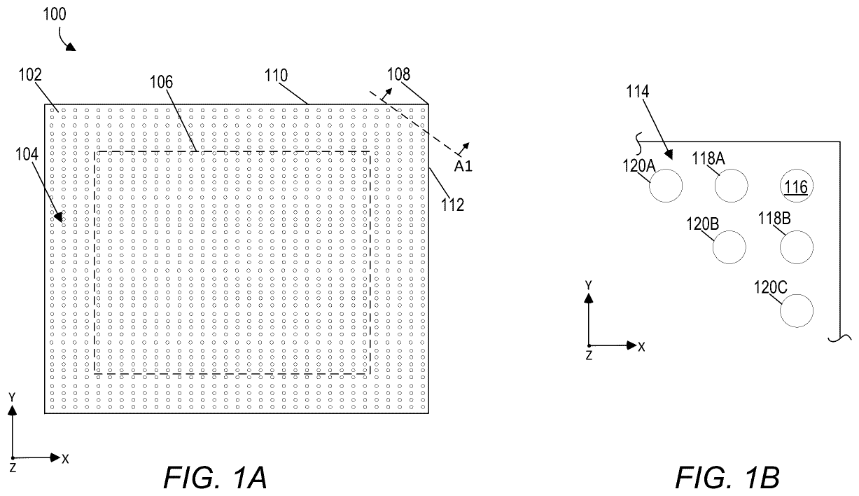

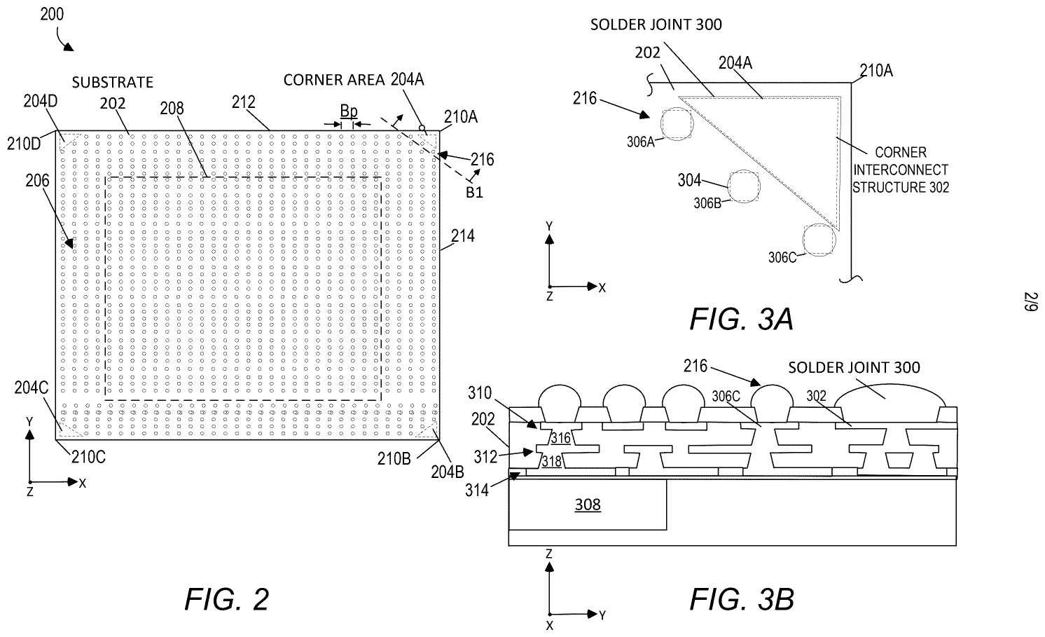

Before discussing exemplary aspects starting at FIG. 2A, FIG. 1A is a bottom view of an IC package 100 utilizing a set of dummy solder balls in a corner of the IC package 100. The IC package 100 includes a substrate 102 and a ball grid array 104 coupled to the substrate 102. The IC package 100 also includes a die. The die has die footprint area 106. The substrate 102 has four corners including corner 108 at the intersection of a first edge 110 and a second edge 112.

FIG. 1B is close-up view of FIG. 1A at cut line A1. The ball grid array 104 includes a set of dummy solder balls 114 in the area defined by cut line A1. The set of dummy balls 114 includes a first tier solder ball 116, a row of second tier solder balls 118A-118B, and a row of third tier solder balls 120A-120C. Thermal and mechanical stress propagates from the corners 108 of the substrate 102 toward the center of the IC package 100 over the lifetime of the IC package 100. The set of dummy solder balls 114 is not coupled to active circuits that carry information and whose purpose is to provide mechanical support of the package. The solder balls of the ball grid array 104 outside the die footprint area 106 excluding the set of dummy balls 114 are referred to as I/O solder balls and carry I/O information. As the complexity and capacity of ICs progress to future generations of ICs, the need for additional I/O solder balls increases. To add additional I/O solder balls to the IC package 100, the size of the IC package 100 has to be increased. For example, to gain eight I/O solder balls outside the die footprint area 106 in the IC package 100, the IC package 100 would need to increase at least the height of one row plus margin in the Y-direction. As such, there is a need to increase the number of I/O solder balls without increasing the size of the IC package.

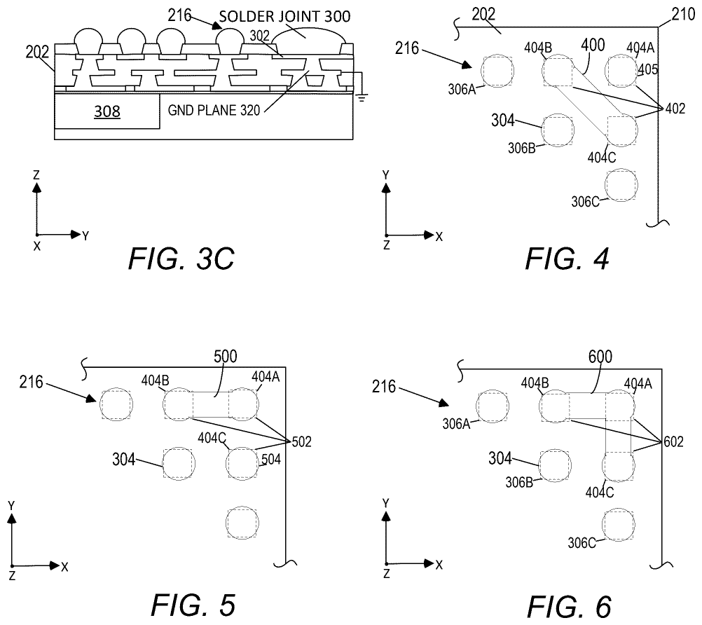

To this end, FIG. 2 is a bottom view of an IC package 200 comprising a substrate 202 and a solder joint (not shown) coupled to a corner interconnect structure (not shown) in a corner area 204A of the substrate 202 to improve the reliability of the package. The IC package 200 also includes a ball grid array 206 coupled to the substrate 202. The ball grid array 206 has a ball pitch Bp between any two solder balls in either the Y-direction or the X-direction. The ball pitch Bp may vary and decrease over different iterations of IC packages. Typical values for the ball pitch Bp are 0.325 millimeters (mm), 0.35 mm, or 0.4 mm. The IC package 200 also includes a die. The die has a die footprint area 208. The substrate 202 has four corners 29A-29D including corner 29A. A corner, as discussed herein, is an intersection between two edges of a substrate including edge 212 and edge 214. The IC package 200 includes four corners including corner areas 204A-204D to which four solder joints may couple to four corresponding corner interconnect structures, respectively. The solder joint coupled to the corner interconnect structure at corner area 204A provides mechanical reliability to the IC package 200 and enables solder balls 216 (also referred to as I/O solder balls) to be utilized as I/O increasing the number of I/O balls without increasing the size of the IC package 200. The solder joint coupled to the corner interconnect structure will be discussed in more detail in connection with FIGS. 3A-3C, and 4-6.

In this regard, FIG. 3A is a close-up view of FIG. 2 at cut line B1 including an exemplary embodiment of a solder joint 300 coupled to a corner interconnect structure 302 deployed at one or more corner areas 204A-204D of the substrate of FIG. 2 such as the corner area 204A. Common elements in FIGS. 3A-3C and FIG. 2 are shown with common element numbers. The substrate 202 includes the corner interconnect structure 302 which is also referred to as a merged metal interconnect 302 because, as will be described in connection with FIGS. 4-6, the subsequent embodiments described in FIGS. 4-6 have separate metal interconnects coupled to a respective solder joint. The merged metal interconnect has a triangle shape. I/O solder balls 216 are adjacent to the corner interconnect structure 302. The solder joint 300 is coupled to the merged metal interconnect 302. A footprint area 304 for each of the solder balls 216 and a footprint area of the solder joint 300 can vary depending on the ball pitch. For example, for a ball pitch of 0.325 mm, the footprint area 304 for each of the solder balls 216 would be 0.025 square millimeters (mm² ) while the footprint area of the solder joint 300 would be 0.13 mm² . In another example, the footprint area 304 for each of the solder balls 216 would be 0.03 mm² for a ball pitch of 0.35 mm while the footprint area of the solder joint 300 would be 0.15 mm² . In another example, the footprint area 304 for each of the solder balls 216 would be 0.04 mm² for a ball pitch of 0.4 mm while the footprint area of the solder joint 300 would be 0.2 mm². In this regard, for those respective ball pitches, the ratios of the footprint area of the solder joint 300 to the footprint area 304 of each of the solder balls 216 are 5.2, 5, and 5 respectively. The I/O solder balls 216 are soldered to metal interconnects 306A-306C.

FIG. 3B is horizontal view of the exemplary embodiment of FIG. 3A. A die 308 is attached to the substrate 202 and has the die footprint 208. The substrate 202 includes an outer metallization layer 310 which includes metal interconnects such as metal interconnect 306C and the corner interconnect structure 302. Metal interconnects couple to the die 308 through additional metallization layers 312 and 314 which are coupled by vias such as vias 316 and 318. Common elements in FIG. 3B and FIGS. 2 and 3A are shown with common element numbers.

FIG. 3C is horizontal view of the exemplary embodiment of FIG. 3A wherein the corner interconnect structure 302 is connected to a ground plane 320. Common elements in FIG. 3C and FIGS. 2 and 3A-3B are shown with common element numbers.

FIG. 4 is a close-up view of FIG. 2 at cut line B1 including another exemplary embodiment of a solder joint 400 coupled to a corner interconnect structure 402 deployed at one or more corner areas 204A-204D of the substrate 202 of FIG. 2. Common elements in FIG. 4 and FIGS. 2, and 3A-3C are shown with common element numbers. The substrate 202 includes the corner interconnect structure 402 comprising a first metal interconnect 404A adjacent to the corner 29A and second metal interconnects 404B, 404C adjacent to the first metal interconnect 404A. The I/O solder balls 216 are adjacent to the corner interconnect structure 402, and more particularly, the second metal interconnects 404B, 404C. The solder joint 400 is coupled to the first metal interconnect 404A and the second metal interconnects 404B, 404C of the corner interconnect structure 402. The second metal interconnect 404B is also referred to as the first second metal interconnect and the second metal interconnect 404C is also referred to as the last second metal interconnect. The solder joint 400 connects the first second metal interconnect 404B to the last second metal interconnect 404C. A solder ball 404 is soldered to the first metal interconnect 404A and has the same footprint area as each of the solder balls 216 described in connection with FIG. 3A which varies with ball pitch. The footprint area of the solder joint 400 also varies with ball pitch. For example, for a ball pitch of 0.325 mm, the footprint area 304 for each of the solder balls 216 would be 0.025 mm² while the footprint area of the solder joint 400 would be 0.1 mm² and the footprint area of the metal interconnect supporting a solder ball 216, such as metal interconnect 404A, would be 0.025 mm². In another example, the footprint area 304 for each of the solder balls 216 would be 0.03 mm² for a ball pitch of 0.35 mm while the footprint area of the solder joint 400 would be 0.109 mm² and the footprint area of the metal interconnect supporting a solder ball 216, such as metal interconnect 404A, would be 0.03 mm². In another example, the footprint area 304 for each of the solder balls 216 would be 0.04 mm² for a ball pitch of 0.4 mm while the footprint area of the solder joint 400 would be 0.142 mm² and the footprint area of the metal interconnect supporting a solder ball 216, such as metal interconnect 404A, would be 0.04 mm². In this regard, for those respective ball pitches, the ratios of the footprint area of the solder joint 400 to the footprint area of a metal interconnect supporting solder balls 216 are 4, 3.6, and 3.55, respectively.

FIG. 5 is a close-up view of FIG. 2 at cut line B1 including another exemplary embodiment of a solder joint 500 coupled to a corner interconnect structure 502 deployed at one or more corner areas 204A-204D of the substrate 202 of FIG. 2. Common elements in FIG. 5 and FIGS. 2, 3A-3C, and 4 are shown with common element numbers. The solder joint 500 connects the first metal interconnect 404A to the first second metal interconnect 404B. A solder ball 504 is connected to the last second metal interconnect 304C and has the same footprint area as each of the solder balls 216 described in connection with FIG. 3A which varies with ball pitch. The footprint area of the solder joint 500 also varies with ball pitch. For example, for a ball pitch of 0.325 mm, the footprint area 304 for each of the solder balls 216 would be 0.025 mm² while the footprint area of the solder joint 500 would be 0.09 mm² and the footprint area of the metal interconnect supporting a solder ball 216, such as metal interconnect 404C, would be 0.025 mm². In another example, the footprint area 304 for each of the solder balls 216 would be 0.03 mm² for a ball pitch of 0.35 mm while the footprint area of the solder joint 500 would be 0.1 mm² and the footprint area of the metal interconnect supporting a solder ball 216, such as metal interconnect 404C, would be 0.03 mm². In another example, the footprint area 304 for each of the solder balls 216 would be 0.04 mm² for a ball pitch of 0.4 mm while the footprint area of the solder joint 500 would be 0.137 mm² and the footprint area of the metal interconnect supporting a solder ball 216, such as metal interconnect 404C, would be 0.04 mm². In this regard, for those respective ball pitches, the ratios of the footprint area of solder joint 500 to the footprint area of each of the solder balls 216 are 3.6, 3.33, and 3.425, respectively.

FIG. 6 is a close-up view of FIG. 2 at cut line B1 including another exemplary embodiment of a solder joint 600 coupled to a corner interconnect structure 602 deployed at one or more corner areas 204A-204D of the substrate 202 of FIG. 2. Common elements in FIG. 6 and FIGS. 2, 3A-3C, and 4 are shown with common element numbers. The solder joint 600 connects the first metal interconnect 404A to the first second metal interconnect 404B and connects the first metal interconnect 404A to the last second metal interconnect 404C. The footprint area of the solder joint 600 also varies with ball pitch. For example, for a ball pitch of 0.325 mm, the footprint area 304 of the metal interconnect supporting a solder ball 216, such as metal interconnect 306B, would be 0.025 mm² while the footprint area of the solder joint 600 would be 0.1 mm² . In another example, the footprint area 304 of the metal interconnect supporting a solder ball 216, such as metal interconnect 306B, would be 0.03 mm² for a ball pitch of 0.35 mm while the footprint area of the solder joint 600 would be 0.11 mm². In another example, the footprint area 304 of the metal interconnect supporting a solder ball 216, such as metal interconnect 306B, would be 0.04 mm² for a ball pitch of 0.4 mm while the footprint area of the solder joint 600 would be 0.15 mm². In this regard, for those respective ball pitches, the ratios of the footprint area of the solder joint 600 to the footprint area 304 of each of the solder balls 216 are 4, 3.66, and 3.75, respectively. In summary, the ratios of the footprint areas of solder joints 400, 500, and 600 to footprint areas of a metal interconnect supporting a respective solder ball 216 ranges between 3 and 4.

Each corner 29A-29D may include a solder joint, such as solder joints 300, 400, 500, and 600, coupled to a respective corner interconnect structure, such as corner interconnect structure 302, 402, 502, and 602.

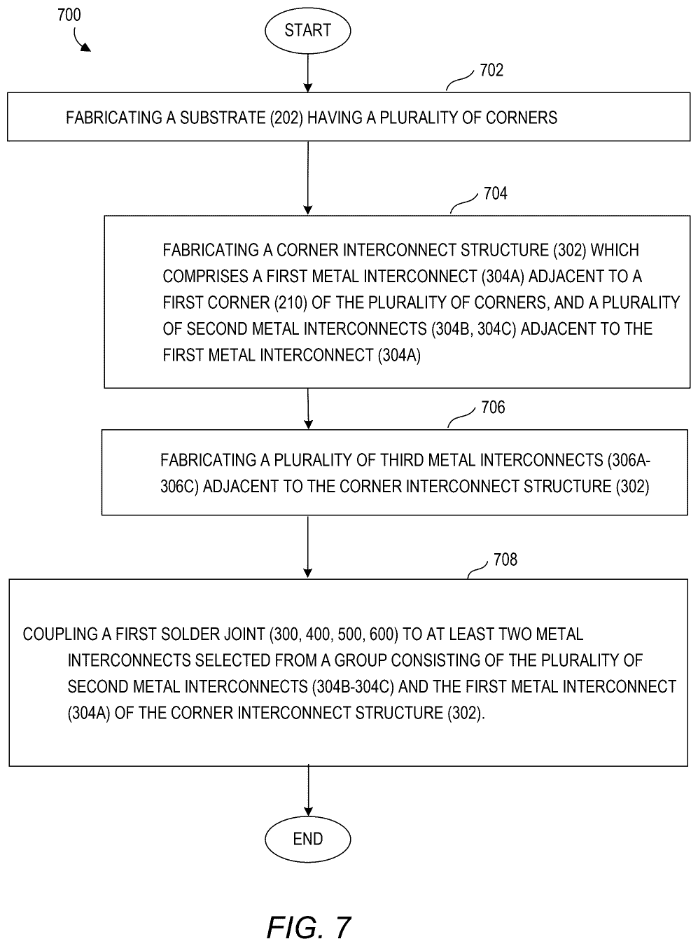

An IC package comprising a substrate and a solder joint coupled to a corner interconnect structure of the substrate to improve the reliability of the package including, but not limited to, the solder joints 300, 400, 500, and 600 in FIGS. 3-6 and deployed in the IC package 200 in FIG. 2 can be fabricated by different fabrication processes. FIG. 7 is a flowchart illustrating an exemplary fabrication process of fabricating an IC package comprising a solder joint coupled to the corner interconnect structure including, but not limited to, the solder joints 300, 400, 500, and 600 in FIGS. 3A-3C and 4-6.

In this regard, a first exemplary step for fabricating an IC package comprising a solder joint coupled to the corner interconnect structure in the fabrication process 700 of FIG. 7 can include fabricating a substrate 202 having a plurality of corners (block 702, FIG. 7). Fabricating the substrate 202 may include fabricating a corner interconnect structure 302 which comprises a first metal interconnect 304A adjacent to a first corner 210A of the plurality of corners, and a plurality of second metal interconnects 304B, 304C adjacent to the first metal interconnect 304A (block 704, FIG. 7). The next step of fabricating the substrate 202 can include fabricating a plurality of third metal interconnects 306A-306C adjacent to the corner interconnect structure 302 (block 706, FIG. 7). The next step of the fabrication process 700 can include coupling a first solder joint 300, 400, 500, and 600 to at least two metal interconnects selected from a group consisting of the plurality of second metal interconnects 304B-304C and the first metal interconnect 304A of the corner interconnect structure 302 (block 708, FIG. 7).

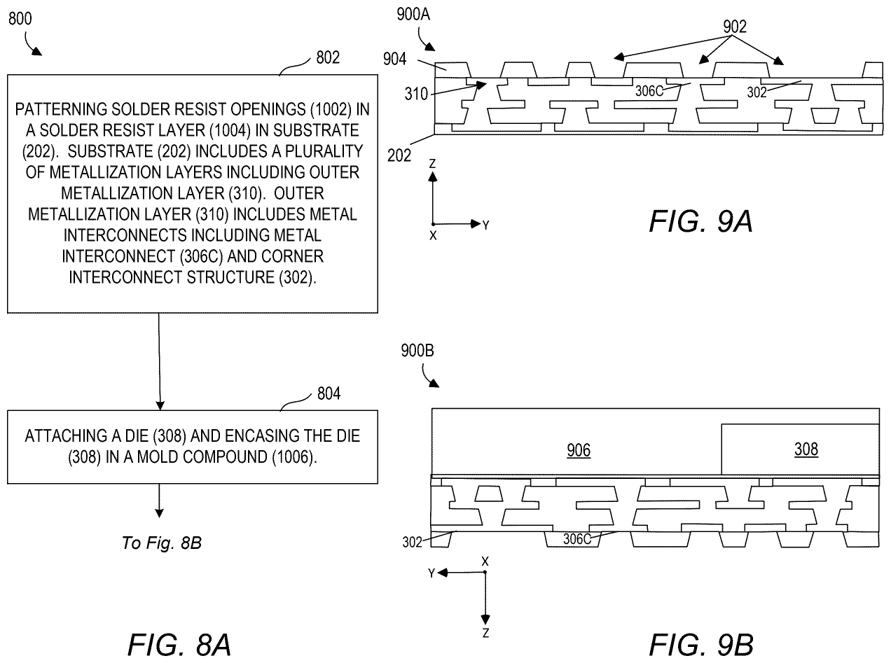

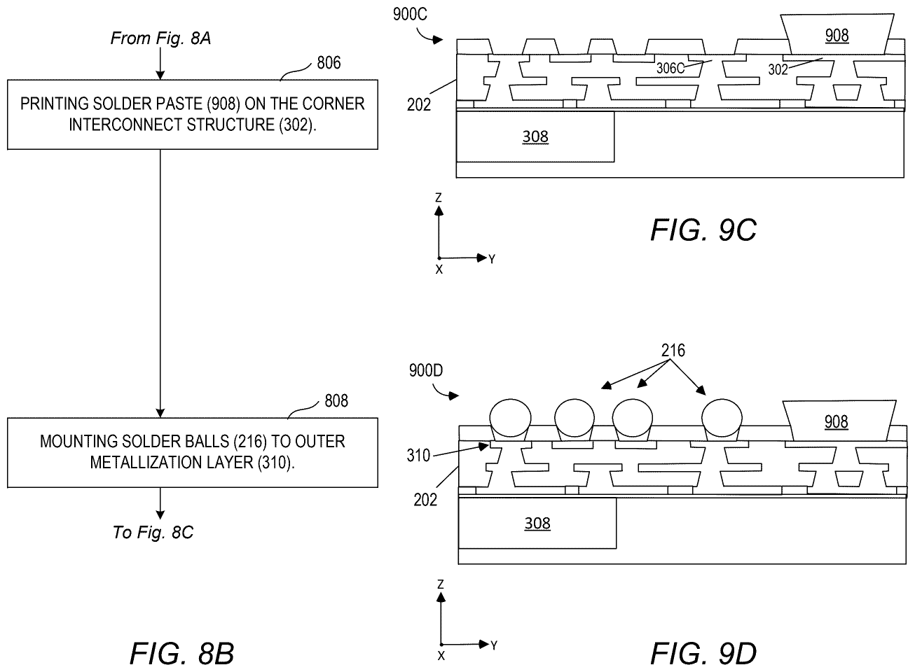

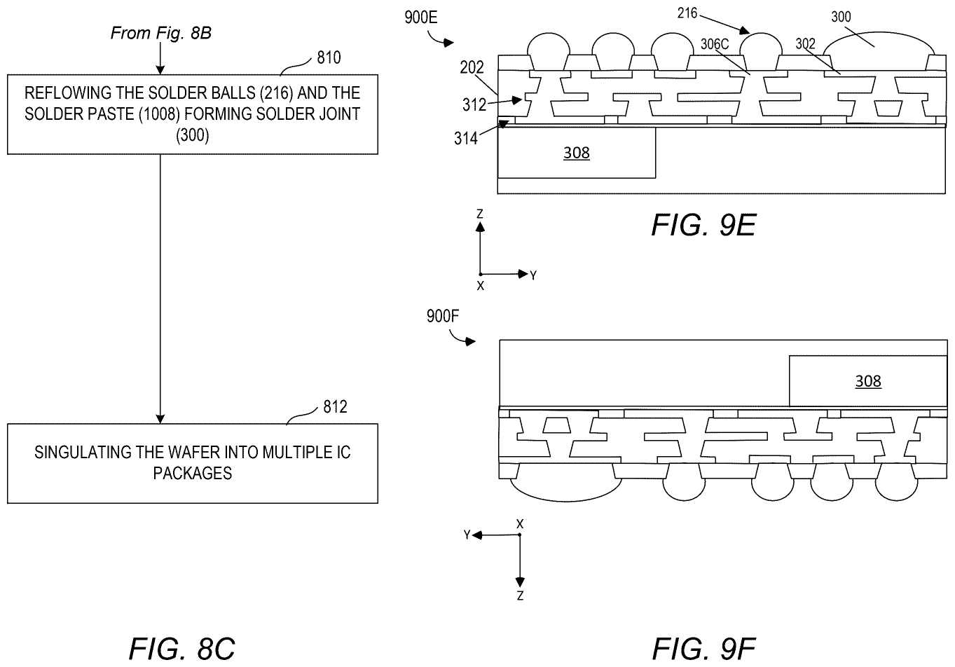

Other fabrication processes can also be employed to fabricate an IC package comprising a solder joint coupled to the corner interconnect structure including, but not limited to, the exemplary solder joints 300, 400, 500, and 600 and the corner interconnect structures 302, 402, 502, and 602 in FIGS. 3A-3C, and 4-6. In this regard, FIGS. 8A-8C is a flowchart of illustrating another exemplary fabrication process 800 for fabricating a solder joint coupled to the corner interconnect structure including, but not limited to, the exemplary solder joints 300, 400, 500, and 600 and the corner interconnect structures 302, 402, 502, and 602 in FIGS. 3A-3C, and 4-6. FIGS. 9A-9F are exemplary fabrication stages during fabrication of the solder joint and corner interconnect structure according to the fabrication process 800 in FIGS. 8A-8C. Fabrication process 800 are described in connection with solder joint 300 and corner interconnect structure 302 for convenience and are applicable to solder joints 400, 500, and 600 and corner interconnect structure 402, 502, and 602, respectively. Additionally, fabrication process 800 will be described as a wafer level process where multiple IC packages are fabricated from one wafer.

In this regard, as shown in fabrication stage 900A in FIG. 9A, an exemplary step in the fabrication process 800 can include patterning solder resist openings 902 in a solder resist layer 904 in the substrate 202 (block 802, FIG. 8A). The substrate 202 includes a plurality of metallization layers including the outer metallization layer 310. The outer metallization layer 310 includes metal interconnects including the metal interconnect 306C and the corner interconnect structure 302. As shown in fabrication stage 900B in FIG. 9B, a next step in the fabrication process 800 can include attaching a die 308 and encasing the die 308 in a mold compound 906 (block 804, FIG. 8A). As shown in fabrication stage 900C in FIG. 9C, a next step in the fabrication process 800 can include printing solder paste 908 on the corner interconnect structure 302 (block 806, FIG. 8B). As shown in fabrication stage 900D in FIG. 9D, a next step in the fabrication process 800 can include mounting solder balls 216 to the outer metallization layer 310 (block 808, FIG. 8B). As shown in fabrication stage 900E in FIG. 9E, a next step in the fabrication process 800 can include reflowing the solder balls 216 and the solder paste 908 forming the solder joint 300 (block 810, FIG. 8C). As shown in fabrication stage 900F in FIG. 9F, a next step in the fabrication process 800 can include singulating the wafer into multiple IC packages (block 812, FIG. 8C).

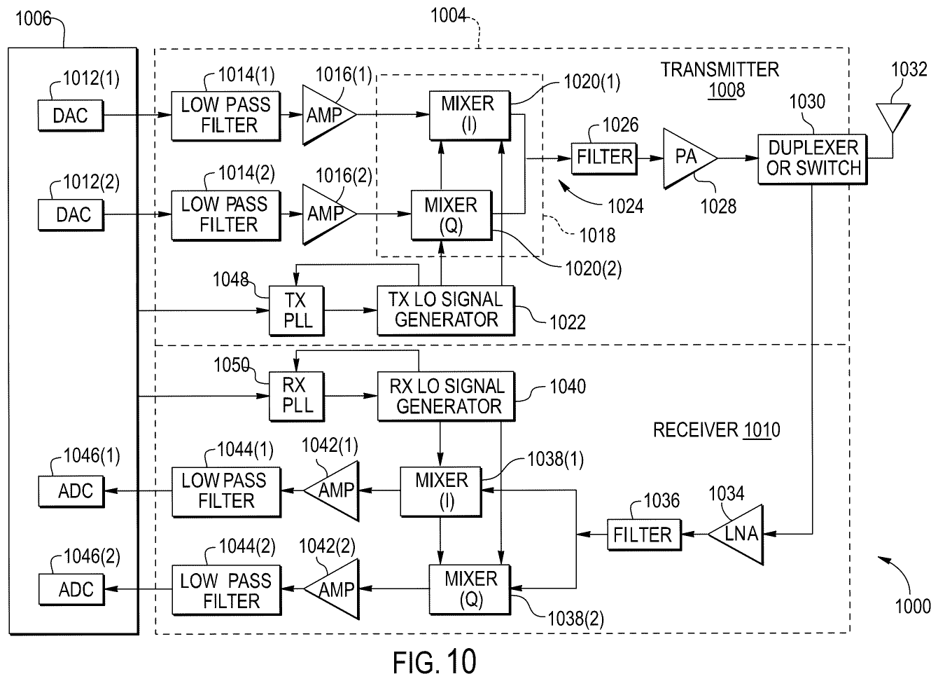

FIG. 10 is a block diagram of an exemplary wireless communications device that includes radio-frequency (RF) components deployed in an IC package, wherein the IC package includes a substrate and a solder joint coupled to a corner interconnect structure of the substrate to improve the reliability of the package, including, but not limited to, the IC package in FIG. 2 and the exemplary embodiments of a solder joint coupled to the corner interconnect structure in FIGS. 3A-3C, and 4-6 according to the exemplary fabrication processes in FIGS. 8 and 8A-8C. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals (e.g., I and Q output currents) for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency up-conversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Down-conversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency up-conversion, while the RX LO signal generator 1040 generates the I and Q RX LO signals used for frequency down-conversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

An IC package which includes a substrate and a solder joint coupled to a corner interconnect structure of the substrate to improve the reliability of the package as disclosed in aspects described herein may be provided in or integrated into an IC and deployed in any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

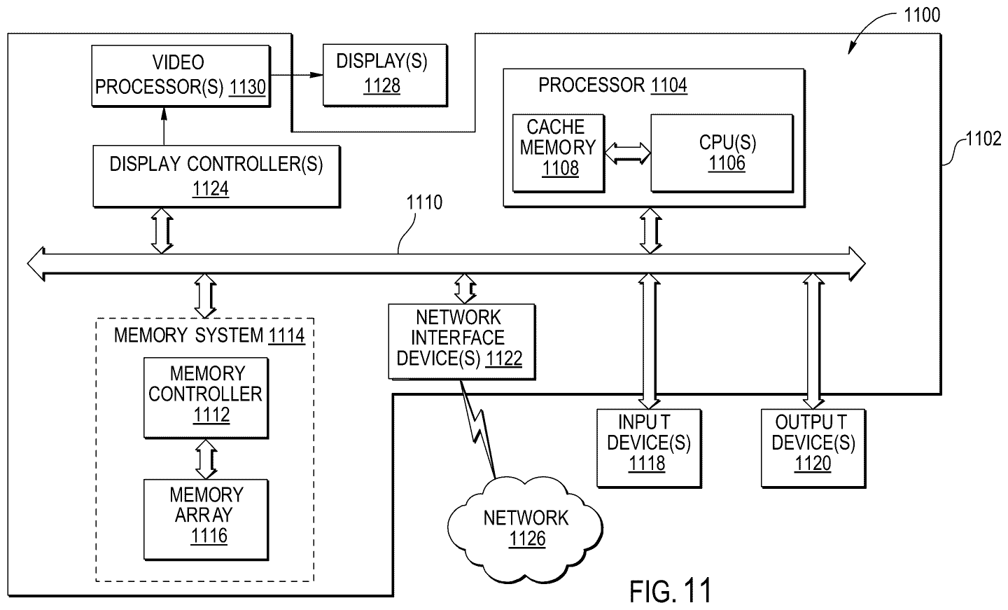

In this regard, FIG. 11 is a block diagram of an exemplary processor-based system 1100 that can include components deployed in an IC package, wherein the IC package includes a substrate and a solder joint coupled to a corner interconnect structure of the substrate to improve the reliability of the package, including, but not limited to, the IC package in FIG. 2 and the exemplary embodiments of a solder joint coupled to the corner interconnect structure in FIGS. 3A-3C, and 4-6 according to the exemplary fabrication processes in FIGS. 8 and 8A-8C.

In this example, the processor-based system 1100 may be deployed on a substrate 1102 and includes a processor 1104 including one or more central processing units (captioned as “CPUs” in FIG. 11) 1106, which may also be referred to as CPU cores or processor cores. The processor 1104 may have cache memory 1108 coupled to the processor 1104 for rapid access to temporarily stored data. The processor 1104 is coupled to a system bus 1110 and can intercouple server and client devices included in the processor-based device 1100. As is well known, the processor 1104 communicates with these other devices by exchanging address, control, and data information over the system bus 1110. For example, the processor 1104 can communicate bus transaction requests to a memory controller 1112, as an example of a client device. Although not illustrated in FIG. 11, multiple system buses 1110 could be provided, wherein each system bus 1110 constitutes a different fabric.

Other server and client devices can be connected to the system bus 1110 and deployed in an IC package such as the IC package 200 in FIG. 2. As illustrated in FIG. 11, these devices can include a memory system 1114 that includes the memory controller 1112 and a memory array(s) 1116, one or more input devices 1118, one or more output devices 1120, one or more network interface devices 1122, and one or more display controllers 1124, as examples. The input device(s) 1118 can include any type of input device, including but not limited to input keys, switches, voice processors, etc. The output device(s) 1120 can include any type of output device, including, but not limited to, audio, video, other visual indicators, etc. The network interface device(s) 1122 can be any device configured to allow exchange of data to and from a network 1126. The network 1126 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1122 can be configured to support any type of communications protocol desired.

The processor 1104 may also be configured to access the display controller(s) 1124 over the system bus 1110 to control information sent to one or more displays 1128. The display controller(s) 1126 sends information to the display(s) 1126 to be displayed via one or more video processors 1130, which process the information to be displayed into a format suitable for the display(s) 1128. The display controller(s) 1124 and/or the video processors 1130 may comprise or be integrated into a GPU. The display(s) 1128 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC) package, comprising:
   a substrate, comprising:
      a plurality of corners;
      a corner interconnect structure comprising:
         a first metal interconnect adjacent to a first corner of the plurality of corners; and
         a plurality of second metal interconnects adjacent to the first metal interconnect; and
      a plurality of third metal interconnects adjacent to the corner interconnect structure; and
   a first solder joint coupled to at least two metal interconnects selected from a group consisting of the plurality of second metal interconnects and the first metal interconnect of the corner interconnect structure.
2. The IC package of clause 1, wherein the plurality of second metal interconnects comprises a first second metal interconnect and a last second metal interconnect, wherein the first solder joint further coupled the first second metal interconnect to the last second metal interconnect, the first second metal interconnect to the first metal interconnect, and the last second metal interconnect to the first metal interconnect.
3. The IC package of clause 1, wherein the first solder joint is further coupled to the at least two metal interconnects selected from the group consisting of the plurality of second metal interconnects of the corner interconnect structure.
4. The IC package of clause 1, wherein the first solder joint is further coupled to the first metal interconnect and one of the plurality of second metal interconnects.
5. The IC package of clause 1, wherein the first solder joint is further coupled to the first metal interconnect and each of the plurality of second metal interconnects.
6. The IC package of any of clauses 1-5, wherein the first solder joint has a first footprint area on the substrate and one of the plurality of third metal interconnects has a second footprint area on the substrate, wherein a ratio of the first footprint area to the second footprint area is between 3 and 4.
7. The IC package of clause 1, wherein the corner interconnect structure further comprises:
a merged metal interconnect comprising:
   the first metal interconnect; and
   the plurality of second metal interconnects, wherein the merged metal interconnect has a triangular shape.
8. The IC package of any of clauses 1-7, wherein the first solder joint is coupled to a ground plane.
9. The IC package of any of clauses 1-8, integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
10. A method of fabricating an integrated circuit (IC) package, comprising:
   fabricating a substrate having a plurality of corners, wherein fabricating the substrate comprises:
      fabricating a corner interconnect structure, comprising:
         fabricating a first metal interconnect adjacent to a first corner of the plurality of corners; and
         fabricating a plurality of second metal interconnects adjacent to the first metal interconnect; and
      fabricating a plurality of third metal interconnects adjacent to the corner interconnect structure; and
   coupling a first solder joint to at least two metal interconnects selected from a group consisting of the plurality of second metal interconnects and the first metal interconnect of the corner interconnect structure.
11. The method of clause 10, wherein the plurality of second metal interconnects comprises a first second metal interconnect and a last second metal interconnect, wherein coupling the first solder joint to the at least two metal interconnects selected from the group consisting of the plurality of second metal interconnects and the first metal interconnect of the corner interconnect structure, further comprises:
   coupling the first second metal interconnect and the last second metal interconnect;
   coupling the first second metal interconnect to the first metal interconnect; and
   coupling the last second metal interconnect to the first metal interconnect.
12. The method of clause 10, wherein coupling the first solder joint to the at least two metal interconnects selected from the group consisting of the plurality of second metal interconnects and the first metal interconnect of the corner interconnect structure, further comprises:
   coupling at least two of the plurality of second metal interconnects of the corner interconnect structure.
13. The method of clause 10, wherein coupling the first solder joint further comprises:
   coupling the first solder joint to the first metal interconnect and one of the plurality of second metal interconnects.
14. The method of clause 10, wherein coupling the first solder joint further comprises:
   coupling the first solder joint to the first metal interconnect and each of the plurality of second metal interconnects.
15. The method of any of clauses 10-14, wherein the first solder joint has a first footprint area on the substrate and one of the plurality of third metal interconnects has a second footprint area on the substrate, wherein a ratio of the first footprint area to the second footprint area is between 3 and 4.
16. The method of clause 10, wherein the corner interconnect structure further comprises:
   a merged metal interconnect comprising:
      the first metal interconnect; and
      the plurality of second metal interconnects, wherein the merged metal interconnect has a triangular shape.
17. The method of any of clauses 10-16, further comprising coupling the first solder joint to a ground plane.

What is claimed is:

1. An integrated circuit (IC) package, comprising:
a substrate, comprising:
a plurality of corners;
a corner interconnect structure comprising:
a first metal interconnect adjacent to a first corner of the plurality of corners; and
a plurality of second metal interconnects adjacent to the first metal interconnect; and
a plurality of third metal interconnects adjacent to the corner interconnect structure; and
a first solder joint coupled to at least two metal interconnects selected from a group consisting of the plurality of second metal interconnects and the first metal interconnect of the corner interconnect structure.

2. The IC package of claim 1, wherein the plurality of second metal interconnects comprises a first second metal interconnect and a last second metal interconnect, wherein the first solder joint further coupled the first second metal interconnect to the last second metal interconnect, the first second metal interconnect to the first metal interconnect, and the last second metal interconnect to the first metal interconnect.

3. The IC package of claim 1, wherein the first solder joint is further coupled to the at least two metal interconnects selected from the group consisting of the plurality of second metal interconnects of the corner interconnect structure.

4. The IC package of claim 1, wherein the first solder joint is further coupled to the first metal interconnect and one of the plurality of second metal interconnects.

5. The IC package of claim 1, wherein the first solder joint is further coupled to the first metal interconnect and each of the plurality of second metal interconnects.

6. The IC package of claim 1, wherein the first solder joint has a first footprint area on the substrate and one of the plurality of third metal interconnects has a second footprint area on the substrate, wherein a ratio of the first footprint area to the second footprint area is between 3 and 4.

7. The IC package of claim 1, wherein the corner interconnect structure further comprises:
a merged metal interconnect comprising:
the first metal interconnect; and
the plurality of second metal interconnects, wherein the merged metal interconnect has a triangular shape.

8. The IC package of claim 1, wherein the first solder joint is coupled to a ground plane.

9. The IC package of claim 1, integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

10. A method of fabricating an integrated circuit (IC) package, comprising:
fabricating a substrate having a plurality of corners, wherein fabricating the substrate comprises:
fabricating a corner interconnect structure, comprising:
fabricating a first metal interconnect adjacent to a first corner of the plurality of corners; and
fabricating a plurality of second metal interconnects adjacent to the first metal interconnect; and
fabricating a plurality of third metal interconnects adjacent to the corner interconnect structure; and
coupling a first solder joint to at least two metal interconnects selected from a group consisting of the plurality of second metal interconnects and the first metal interconnect of the corner interconnect structure.

11. The method of claim 10, wherein the plurality of second metal interconnects comprises a first second metal interconnect and a last second metal interconnect, wherein coupling the first solder joint to the at least two metal interconnects selected from the group consisting of the plurality of second metal interconnects and the first metal interconnect of the corner interconnect structure, further comprises:
coupling the first second metal interconnect and the last second metal interconnect;
coupling the first second metal interconnect to the first metal interconnect; and
coupling the last second metal interconnect to the first metal interconnect.

12. The method of claim 10, wherein coupling the first solder joint to the at least two metal interconnects selected from the group consisting of the plurality of second metal interconnects and the first metal interconnect of the corner interconnect structure, further comprises:
coupling at least two of the plurality of second metal interconnects of the corner interconnect structure.

13. The method of claim 10, wherein coupling the first solder joint further comprises:
coupling the first solder joint to the first metal interconnect and one of the plurality of second metal interconnects.

14. The method of claim 10, wherein coupling the first solder joint further comprises:
coupling the first solder joint to the first metal interconnect and each of the plurality of second metal interconnects.

15. The method of claim 10, wherein the first solder joint has a first footprint area on the substrate and one of the plurality of third metal interconnects has a second footprint area on the substrate, wherein a ratio of the first footprint area to the second footprint area is between 3 and 4.

16. The method of claim 10, wherein the corner interconnect structure further comprises:
a merged metal interconnect comprising:
the first metal interconnect; and
the plurality of second metal interconnects, wherein the merged metal interconnect has a triangular shape.

17. The method of claim 10, further comprising coupling the first solder joint to a ground plane.
